(19) United States
(12) Patent Application Publication
(10) Pub. No.: US 2026/0052976 A1
(43) Pub. Date: Feb. 19, 2026

(54) MEMORY DEVICES AND FORMATION METHOD THEREOF

(71) Applicant: TAIWAN SEMICONDUCTOR MANUFACTURING COMPANY, LTD., Hsinchu (TW)

(72) Inventors: Chia-En HUANG, Hsinchu County (TW); Tzu-Yu CHEN, Kaohsiung City (TW)

(73) Assignee: TAIWAN SEMICONDUCTOR MANUFACTURING COMPANY, LTD., Hsinchu (TW)

(21) Appl. No.: 18/804,464

(22) Filed: Aug. 14, 2024

(51) Int. Cl. H01L 23/528; H10B 61/00; H10N 50/01; H10N 50/10

(52) U.S. Cl. CPC H01L 23/5283; H10B 61/22; H10N 50/01; H10N 50/10

(57) ABSTRACT

A method includes following steps. A metal interconnect structure is formed within a first dielectric layer over a substrate. A second dielectric layer is formed over the first metal interconnect structure. An opening is etched in the second dielectric layer and located over a portion of the first metal interconnect structure. A bottom electrode layer is deposited in the opening. A magnetic tunnel junction (MTJ) layer is deposited in the opening and over the bottom electrode layer. A top electrode layer is deposited in the opening and over the MTJ layer. Portions of the top electrode layer, the MTJ layer, the bottom electrode layer outside the opening in the second dielectric layer are removed to form a top electrode, an MTJ stack, and a bottom electrode confined within the opening in the second dielectric layer.

### BACKGROUND

Many modern-day electronic devices contain electronic memory. Electronic memory may be volatile or non-volatile. Non-volatile memory retains stored data in the absence of power whereas volatile memory does not. Dynamic random-access memory (DRAM) that requires frequent refresh is volatile memory. Non-volatile memory includes, for example, magnetoresistive random-access memory (MRAM), resistive random-access memory (RRAM), ferroelectric random-access memory (FeRAM), phase-change memory (PCM), and so on.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-17A, 17C and 18-19 illustrate cross-sectional views of intermediate stages in formation of an example integrated circuit structure having one or more MRAM cells in accordance with some embodiments of the present disclosure.

FIG. 17B illustrates a top view of the intermediate state of FIG. 17A.

FIG. 20 illustrates a cross-sectional view of another example IC structure in accordance with some embodiments of the present disclosure.

FIGS. 21-24 illustrate cross-sectional views of intermediate stages in formation of an example integrated circuit structure having one or more MRAM cells in accordance with some embodiments of the present disclosure.

FIG. 25 illustrates a cross-sectional view of another example IC structure in accordance with some embodiments of the present disclosure.

FIG. 26 illustrates a cross-sectional view of another example IC structure in accordance with some embodiments of the present disclosure.

FIG. 27 illustrates a cross-sectional view of another example IC structure in accordance with some embodiments of the present disclosure

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

The present disclosure relates to memory cells that are disposed within a back-end-of line (BEOL) metal interconnect of an integrated chip. The BEOL metal interconnect includes a plurality of via s and metal lines that provide interconnects within inter-metal dielectric (IMD) layers. The memory cell may be of a non-volatile type. In some embodiments, the memory cell is magnetoresistive random-access memory (MRAM), resistive random-access memory (RRAM), ferroelectric random-access memory (FeRAM), phase-change memory (PCM), or the like. The data storage layer may include a plurality of layers and its composition depends on the memory type.

Magneto-resistive random-access memory (MRAM) cells each comprise a magnetic tunnel junction (MTJ) cell vertically arranged within an integrated chip back-end-of-the-line (BEOL) between conductive electrodes. An MTJ cell includes first and second ferromagnetic layers separated by a tunnel barrier layer. One of t he ferromagnetic layers (often referred to as a “reference layer” or “pinned layer”) has a fixed magnetization direction (also called magnetization orientation), while the other ferromagnetic layer (often referred to as a “free layer”) has a variable or switchable magnetization direction. For MTJ cells with positive tunnelling magnetoresistance (TMR), if the magnetization directions of the reference layer and free layer are in a parallel orientation, it is more likely that electrons will tunnel through the tunnel barrier layer, such that the MTJ cell is in a low-resistance state. Conversely, if the magnetization directions of the reference layer and free layer are in an anti-parallel orientation, it is less likely that electrons will tunnel through the tunnel barrier layer, such that the MTJ cell is in a high-resistance state. Consequently, the MTJ cell can be switched between two states of electrical resistance, a first state with a low resistance (R_{P}: magnetization directions of reference layer and free layer are parallel) and a second state with a high resistance (R_{AP}: magnetization directions of reference layer and free layer are anti-parallel). Because of their binary nature, MTJ cells can be used to store digital data, with the low resistance state R_{P} corresponding to a first data state (e.g., logical “0”), and the high-resistance state R_{AP} corresponding to a second data state (e.g., logical “1”).

The continuous demand for higher memory density has driven significant advancements in memory technology. However, as the unit cell area decreases, MTJ cells become increasingly susceptible to interference from adjacent MTJ cells, resulting in a higher bit-cell failure rate. This reduction in cell area exacerbates stability issues, such as variations in magnetoresistance and a diminished lifespan of MTJ cells. To address these challenges, the present disclosure in various embodiments provides an improved MTJ cell including an improved MTJ layer that extends a longer dimension in the vertical direction than in the lateral direction. This vertical elongation of the MTJ layer effectively increases the MTJ junction area in the vertical direction, thereby mitigating magnetoresistance variations and enhancing the lifespan of MTJ cells without compromising the cell area.

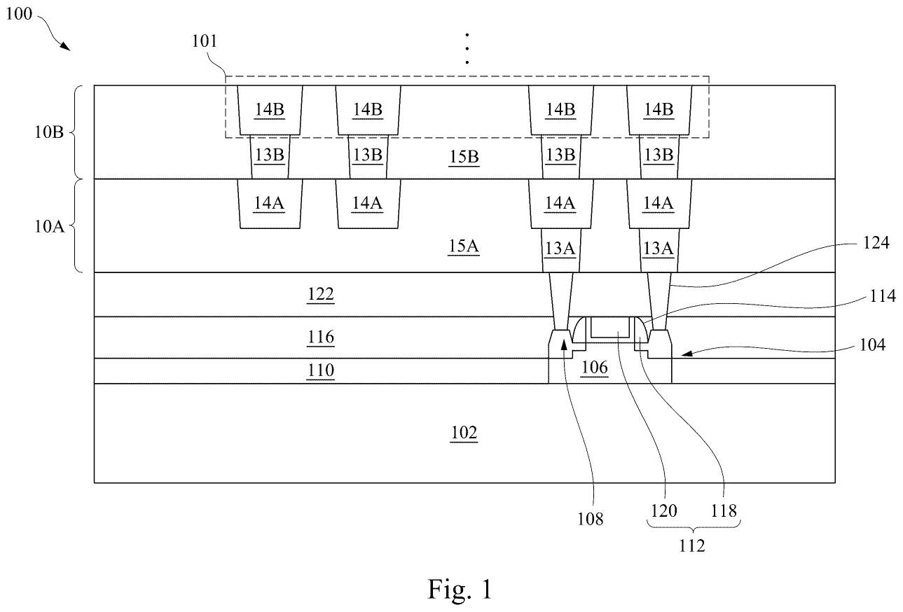

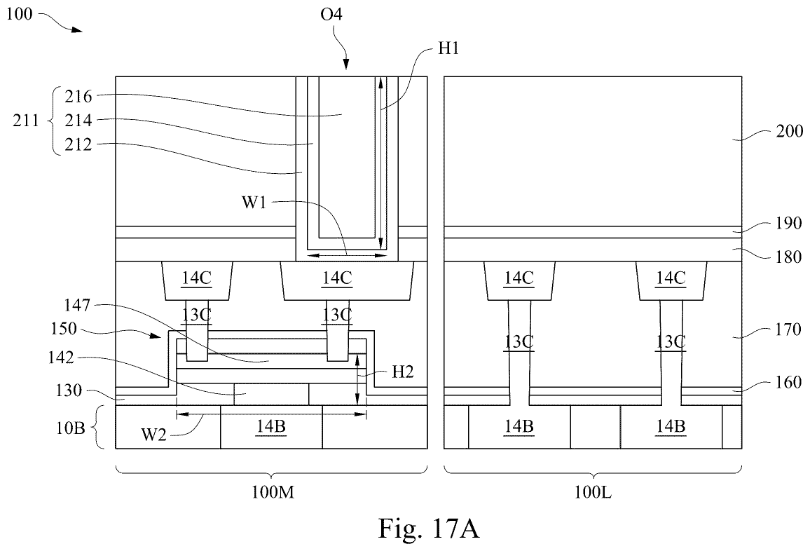

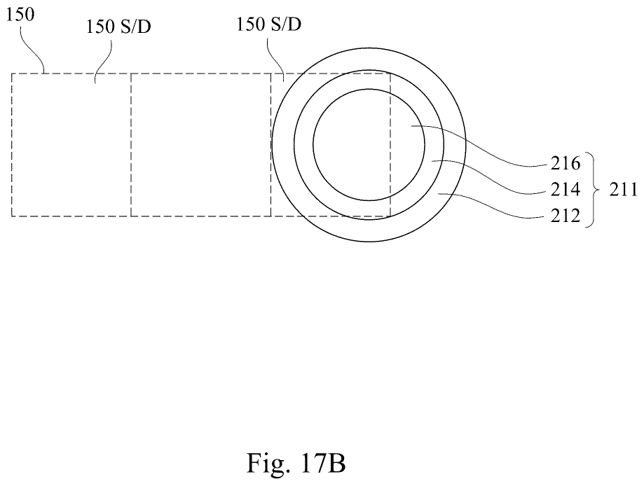

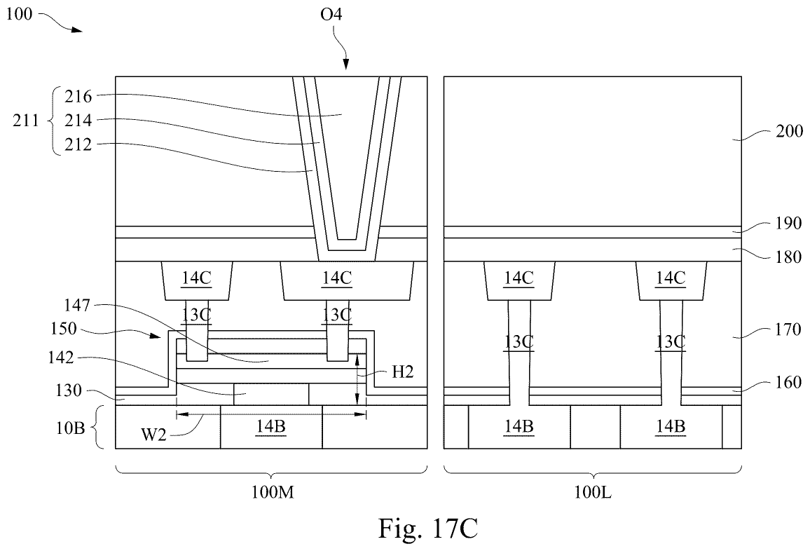

FIGS. 1-17A, 17C and 18-19 illustrate cross-sectional views of intermediate stages in formation of an example integrated circuit structure 100 having one or more MRAM cells in accordance with some embodiments of the present disclosure. FIG. 17B illustrates a top view of the intermediate state of FIG. 17A. Although the cross-sectional views and top views shown in FIGS. 1-19 are described with reference to a method, it will be appreciated that the structures shown in FIGS. 1-19 are not limited to the method but rather may stand alone separate of the method. Although FIGS. 1-19 are described as a series of acts, it will be appreciated that these acts are not limiting in that the order of the acts can be altered in other embodiments, and the methods disclosed are also applicable to other structures.

FIG. 1 illustrates a cross-sectional view of a n example semiconductor structure 100 comprising a semiconductor substrate 102 in which various electronic devices may be formed, and a portion of a multilevel interconnect structure (e.g., interconnect levels 10A and 10B) formed over the substrate 102, in accordance with some embodiments. Generally, FIG. 1 illustrates a transistor 104 formed on the substrate 102, with multiple interconnection layers formed thereover. As indicated by the ellipsis at the top of FIG. 1, multiple interconnect levels may be similarly stacked in the fabrication process of an integrated circuit. As illustrated, the transistor 104 is a FinFET. In some other embodiments, the transistor 104 is a planar FET, a nanosheet FET, or other suitable FET. The transistor 104 can serve as an access transistor for an SOT-MRAM cell in some embodiments.

The substrate 102 illustrated in FIG. 1 may comprise a bulk semiconductor substrate or a silicon-on-insulator (SOI) substrate. An SOI substrate includes an insulator layer 1 below a thin semiconductor layer that is the active layer of the SOI substrate. The semiconductor of the active layer and the bulk semiconductor generally comprise the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

The FinFET device 104 illustrated in FIG. 1 is a three-dimensional MOSFET structure formed in fin-like strips of semiconductor protrusions 106 referred to as fins. The cross-section shown in FIG. 1 is taken along a longitudinal axis of the fin in a direction parallel to the direction of the current flow between the source and drain regions 108. The fin 106 may be formed by patterning the substrate using photolithography and etching techniques. For example, a spacer image transfer (SIT) patterning technique may be used. In this method a sacrificial layer is formed over a substrate and patterned to form mandrels using suitable photolithography and etch processes. Spacers are formed alongside the mandrels using a self-aligned process. The sacrificial layer is then removed by an appropriate selective etch process. Each remaining spacer may then be used as a hard mask to pattern the respective fin 106 by etching a trench into the substrate 102 using, for example, reactive ion etching (RIE). FIG. 1 illustrates a single fin 106, although the substrate 102 may comprise any number of fins.

Shallow trench isolation (STI) regions 110 formed along opposing sidewalls of the fin 106 are illustrated in FIG. 1. STI regions 110 may be formed by depositing one or more dielectric materials (e.g., silicon oxide) to completely fill the trenches around the fins and then recessing the top surface of the dielectric materials. The dielectric materials of the STI regions 110 may be deposited using a high density plasma chemical vapor deposition (HDP-CVD), a low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 110 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 110 such that an upper portion of fin 106 protrudes from surrounding insulating STI regions 110. In some cases, the patterned hard mask used to form the fin 106 may also be removed by the planarization process.

In some embodiments, the gate structure 112 of the FinFET device 104 illustrated in FIG. 1 is a high-k, metal gate (HKMG) gate structure that may be formed using a gate-last process flow. In a gate last process flow a sacrificial dummy gate structure (not shown) is formed after forming the STI regions 110. The dummy gate structure may comprise a dummy gate dielectric, a dummy gate electrode, and a hard mask. First a dummy gate dielectric material (e.g., silicon oxide, silicon nitride, or the like) may be deposited. Next a dummy gate material (e.g. amorphous silicon, polycrystalline silicon, or the like) may be deposited over the dummy gate dielectric and then planarized (e.g., by CMP). A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins and extend between the fins over the surface of the STI regions 110. As described in greater detail below, the dummy gate structure may be replaced by the HKMG gate structure 112 as illustrated in FIG. 1. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

Source and drain regions 108 and spacers 114 of FinFET 104, illustrated in FIG. 1, are formed, for example, self-aligned to the dummy gate structures. Spacers 114 may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structures leaving the spacers 114 along the sidewalls of the dummy gate structures.

Source and drain regions (also collectively referred to as source/drain regions or S/D regions) 108 are semiconductor regions in direct contact with the semiconductor fin 106. In some embodiments, the source and drain regions 108 may comprise heavily-doped regions and relatively lightly-doped drain extensions, or LDD regions. Generally, the heavily-doped regions are spaced away from the dummy gate structures using the spacers 114, whereas the LDD regions may be formed prior to forming spacers 114 and, hence, extend under the spacers 114 and, in some embodiments, extend further into a portion of the semiconductor fin 106 below the dummy gate structure. The LDD regions may be formed, for example, by implanting dopants (e.g., As, P, B, In, or the like) using an ion implantation process.

In some embodiments, t he source and drain regions 108 may comprise an epitaxially grown region. For example, after forming the LDD regions, the spacers 114 may be formed and, subsequently, the heavily-doped source and drain regions may be formed self-aligned to the spacers 114 by first etching the fins 106 to form recesses, and then depositing a crystalline semiconductor material in the recess by a selective epitaxial growth (SEG) process that may fill the recess and, typically, extend beyond the original surface of the fin to form a raised source-drain structure, as illustrated in FIG. 1. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁴ cm⁻² to 10¹⁸ cm⁻²) of dopants may be introduced into the heavily-doped source and drain regions 108 either in situ during SEG, or by an ion implantation process performed after the SEG, or by a combination thereof.

A first interlayer dielectric (ILD) 116 is deposited over the structure. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., CMP) may be performed to remove excess ILD material and any remaining hard mask material from over the dummy gates to form a top surface wherein the top surface of the dummy gate material is exposed and may be substantially coplanar with the top surface of the first ILD 116. The HKMG gate structures 112, illustrated in FIG. 1, may then be formed by first removing the dummy gate structures using one or more etching techniques, thereby creating trenches between respective spacers 114. Next, a replacement gate dielectric layer 118 comprising one more dielectrics, followed by a replacement conductive gate layer 120 comprising one or more conductive materials, are deposited to completely fill the recesses. Excess portions of the gate structure layers 118 and 120 may be removed from over the top surface of first ILD 116 using, for example a CMP process. The resulting structure, as illustrated in FIG. 1, may be a substantially coplanar surface comprising an exposed top surface of first ILD 116, spacers 114, and remaining portions of the HKMG gate layers 118 and 120 inlaid between respective spacers 114.

The gate dielectric layer 118 includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof. In some embodiments, the conductive gate layer 120 may be a multilayered metal gate stack comprising a barrier layer, a work function layer, and a gate-fill layer formed successively on top of gate dielectric layer 118. Example materials for a barrier layer include TiN, TaN, Ti, Ta, or the like, or a multilayered combination thereof. A work function layer may include TiN, TaN, Ru, Mo, Al, for a p-type FET, and Ti, Ag, TaAl, TaAlC, TiAlN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, physical vapor deposition (PVD), ALD, PEALD, electrochemical plating (ECP), electroless plating and/or the like.

A second ILD layer 122 may be deposited over the first ILD layer 116, as illustrated in FIG. 1. In some embodiments, the insulating materials to form the first ILD layer 116 and the second ILD layer 122 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g. xerogels/aerogels), or the like, or a combination thereof. The dielectric materials used to form the first ILD layer 116 and the second ILD layer 122 may be deposited using any suitable method, such as CVD, physical vapor deposition (PVD), ALD, PEALD, PECVD, SACVD, FCVD, spin-on, and/or the like, or a combination thereof.

As illustrated in FIG. 1, electrodes of electronic devices formed in the substrate 102 may be electrically connected to conductive features of a first interconnect level 10A using conductive connectors (e.g., contacts 124) formed through the intervening dielectric layers. In the embodiment illustrated in FIG. 1, the contacts 124 make electrical connections to the source and drain regions 108 of FinFET 104. Contacts 124 to gate electrodes may be formed over STI regions 110, and thus are not shown in the cross-section view of FIG. 1. The contacts may be formed using photolithography techniques. For example, a patterned mask may be formed over the second ILD 122 and used to etch openings that extend through the second ILD 116 to expose a portion of gate structures 112, as well as etch openings that extend further through the first ILD 116 and the CESL (if present) liner below first ILD 116 to expose portions of the source and drain regions 108.

In some embodiments, a conductive liner may be formed in the openings in the first ILD layer 116 and the second ILD layer 122. Subsequently, the openings are filled with a conductive fill material. The liner comprises barrier metals used to reduce out-diffusion of conductive materials from the contacts 124 into the surrounding dielectric materials. In some embodiments, the liner may comprise two barrier metal layers. The first barrier metal comes in contact with the semiconductor material in the source and drain regions 108 and may be subsequently chemically reacted with the heavily-doped semiconductor in the source and drain regions 108 to form a low resistance ohmic contact, after which the unreacted metal may be removed. For example, if the heavily-doped semiconductor in the source and drain regions 108 is silicon or silicon-germanium alloy semiconductor, then the first barrier metal may comprise Ti, Ni, Pt, Co, other suitable metals, or their alloys. The second barrier metal layer of the conductive liner may additionally include other metals (e.g., TiN, TaN, Ta, or other suitable metals, or their alloys). A conductive fill material (e.g., W, Al, Cu, Ru, Ni, Co, alloys of these, combinations thereof, and the like) may be deposited over the conductive liner layer to fill the contact openings, using any acceptable deposition technique (e.g., CVD, ALD, PEALD, PECVD, PVD, ECP, electroless plating, or the like, or any combination thereof). Next, a planarization process (e.g., CMP) may be used to remove excess portions of all the conductive materials from over the surface of the second ILD 122. The resulting conductive plugs extend into the first and second ILD layers 116 and 122 and constitute contacts 124 making physical and electrical connections to the electrodes of electronic devices, such as the tri-gate FinFET 104 illustrated in FIG. 1.

As illustrated in FIG. 1, after the front-end-of-line (FEOL) processing for forming the transistors 104 is completed, multiple interconnect levels may be formed, stacked vertically above the contact plugs 124 formed in the first and second ILD layers 116 and 122, in accordance with a back end of line (BEOL) scheme adopted for the integrated circuit design. In the BEOL scheme illustrated in FIG. 1, various interconnect levels have similar features. However, it is understood that other embodiments may utilize alternate integration schemes wherein the various interconnect levels may use different features. For example, the contacts 124, which are shown as vertical connectors, may be extended to form conductive lines which transport current laterally.

In this disclosure, the second interconnect level comprises conductive vias and lines embedded in an inter-metal dielectric (IMD) layer. In addition to providing insulation between various conductive elements, an IMD layer may include one or more dielectric etch stop layers to control the etching processes that form openings in the IMD layer. Generally, vias conduct current vertically and are used to electrically connect two conductive features located at vertically adjacent levels, whereas lines conduct current laterally and are used to distribute electrical signals and power within one level. In the BEOL scheme illustrated in FIG. 1, conductive vias 13A connect contacts 124 to conductive lines 14A and, at subsequent levels, vias connect lower lines to upper lines (e.g., a pair of lines 14A and 14B can be connected by via 13B). Other embodiments may adopt a different scheme. For example, vias 13A may be omitted from the second level and the contacts 124 may be configured to be directly connected to lines 14A.

The first interconnect level 10A may be formed using, for example, a dual damascene process flow. First, a dielectric stack used to form IMD layer 15A may be deposited using one or more layers of the dielectric materials listed in the description of the first and second ILD layers 116 and 122. In some embodiments, IMD layer 15A includes an etch stop layer (not shown) positioned at the bottom of the dielectric stack. The etch stop layer comprises one or more insulator layers (e.g., SiN, SiC, SiCN, SiCO, CN, combinations thereof, or the like) having an etch rate different than an etch rate of an overlying material. The techniques used to deposit the dielectric stack for IMD may be the same as those used in forming the first and second ILD layers 116 and 122.

Appropriate photolithography and etching techniques (e.g., anisotropic RIE employing fluorocarbon chemistry) may be used to pattern the IMD layer 15A to form openings for vias and lines. The openings for vias may be vertical holes extending through IMD layer 15A to expose a top conductive surface of contacts 124, and openings for lines may be longitudinal trenches formed in an upper portion of the IMD layer 15A. In some embodiments, the method used to pattern holes and trenches in IMD layer 15A utilizes a via-first scheme, wherein a first photolithography and etch process form holes for vias, and a second photolithography and etch process form trenches for lines. Other embodiments may use a different method, for example, a trench-first scheme, or an incomplete via-first scheme, or a buried etch stop layer scheme. The etching techniques may utilize multiple steps. For example, a first main etch step may remove a portion of the dielectric material of IMD layer 15A and stop on an etch stop dielectric layer. Then, the etchants may be switched to remove the etch stop layer dielectric materials. The parameters of the various etch steps (e.g., chemical composition, flow rate, and pressure of the gases, reactor power, etc.) may be tuned to produce tapered sidewall profiles with a desired interior taper angle.

Several conductive materials may be deposited to fill the holes and trenches forming the conductive features 13A and 14A of the first interconnect level 10A. The openings may be first lined with a conductive diffusion barrier material and then completely filled with a conductive fill material deposited over the conductive diffusion barrier liner. In some embodiments, a thin conductive seed layer may be deposited over the conductive diffusion barrier liner to help initiate an electrochemical plating (ECP) deposition step that completely fills the openings with a conductive fill material.

The diffusion barrier conductive liner in the vias 13A and lines 14A comprises one or more layers of TaN, Ta, TiN, Ti, Co, or the like, or combinations thereof. The conductive fill layer in the vias 13A and lines 14A may comprise metals such as Cu, Al, W, Co, Ru, or the like, or combinations thereof, or multi-layers thereof. The conductive materials used in forming the conductive features 13A and 14A may be deposited by any suitable method, for example, CVD, PECVD, PVD, ALD, PEALD, ECP, electroless plating and the like. In some embodiments, the conductive seed layer may be of the same conductive material as the conductive fill layer and deposited using a suitable deposition technique (e.g., CVD, PECVD, ALD, PEALD, or PVD, or the like).

Any excess conductive material over the IMD layer 15A outside of the openings may be removed by a planarizing process (e.g., CMP) thereby forming a top surface comprising dielectric regions of IMD layer 15A that are substantially coplanar with conductive regions of the conductive lines 14A. The planarization step embeds the conductive vias 13A and conductive lines 14A into IMD layer 15A, as illustrated in FIG. 1.

The interconnect level positioned vertically above the first interconnect level 10A in FIG. 1, is the second interconnect level 10B. In some embodiments, the structures of the various interconnect levels (e.g., the first interconnect level 10A and the second interconnect level 10B) may be similar. In the example illustrated in FIG. 1, the second interconnect level 10B comprises conductive vias 13B and conductive lines 14B embedded in an insulating film IMD layer 15B having a planar top surface. The materials and processing techniques described above in the context of the first interconnect level 10A may be used to form the second interconnect level 10B and subsequent interconnect levels.

Although an example electronic device (FinFET 104) and example interconnect structures making connections to the electronic device are described, it is understood that one of ordinary skill in the art will appreciate that the above examples are provided for illustrative purposes only to further explain applications of the present embodiments, and are not meant to limit the present embodiments in any manner.

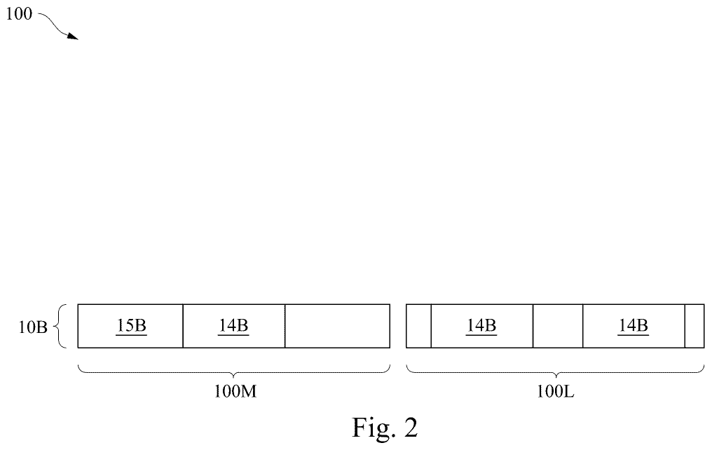

FIG. 2 illustrates a zoomed-in view of a region 101 of FIG. 1, showing an upper region of an interconnect level 10B at an initial stage of fabrication of the IC structure 100. In FIG. 2, conductive lines 14B are shown embedded in an IMD layer 15B. The top dielectric surface of the IMD layer 15B is shown to be substantially coplanar with the top conductive surfaces of conductive lines 14B, within process variations. The IC structure 100 includes a logic region 100L and a memory region 100M. Memory devices (e.g., MRAM devices) are formed in the memory region 100M and logic devices (e.g., logic circuits) are formed in the logic region 100L. Each region includes a plurality of transistors (e.g., FinFETs 104) for controlling operations of MRAM devices and/or logic circuits.

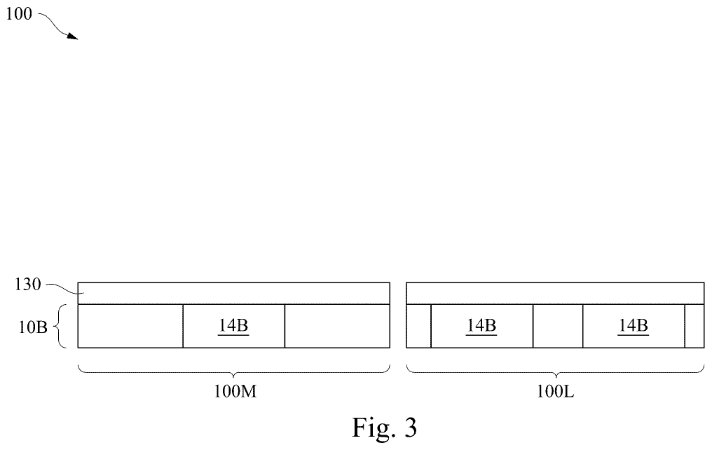

In FIG. 3, a dielectric layer (also referred to as a dielectric barrier layer (SBL)) 130 is formed spanning the memory region 100M and the logic region 100L. In some embodiments, the dielectric layer 210 may include one or more dielectric materials such as Si₃N₄, SiON, SiC, SiCN, or a combination thereof in various embodiments. The dielectric layer 130 may be formed by any suitable deposition process, such as spin coating, physical vapor deposition (PVD), chemical vapor deposition (CVD), the like, or a combination thereof.

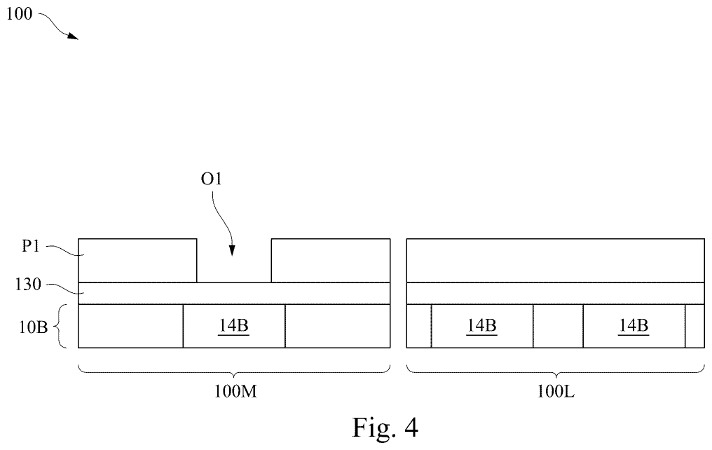

In FIG. 4, a patterned mask P1 is formed over the dielectric layer 130. In some embodiments, the patterned mask P1 is a patterned photoresist formed using suitable photolithography process. In an example photolithography process, photoresist material is irradiated (exposed) and developed to remove portions of the photoresist material. In greater detail, a photomask or reticle (not shown) may be placed above the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material. A developer may be used to remove either the exposed or unexposed portions of the photoresist material depending on whether a positive or negative resist is used, leaving a patterned photoresist mask P1 over the dielectric layer 130, with an opening O1 exposing a portion of the dielectric layer 130.

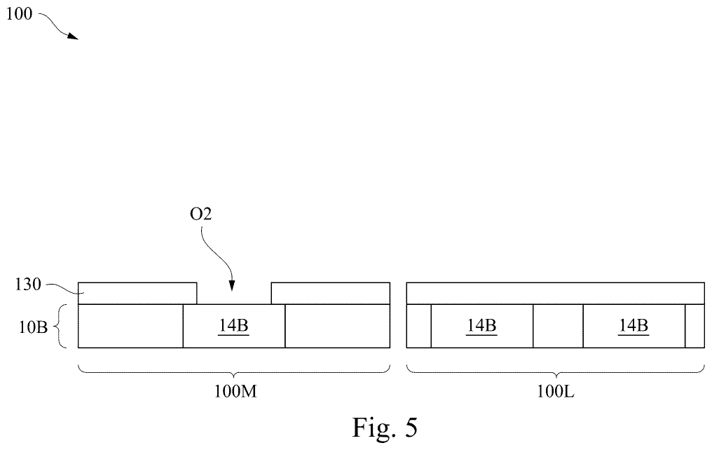

In FIG. 5, the dielectric layer 130 patterned in an etching process by using the patterned mask P1 as an etch mask, creating an opening O2 extending through the dielectric layer 130 to expose a conductive line 14B. The dielectric layer 130 can be patterned by using suitable etching techniques, such as wet etching, dry etching, or combinations thereof. After forming the opening O2 in the dielectric layer 130, the patterned mask P1 can be removed, for example, using a plasma ash process. In some embodiments, a plasma ash process is performed such that the temperature of the photoresist is increased until the photoresist experiences a thermal decomposition and may be removed. However, any other suitable process, such as a wet strip, may be utilized.

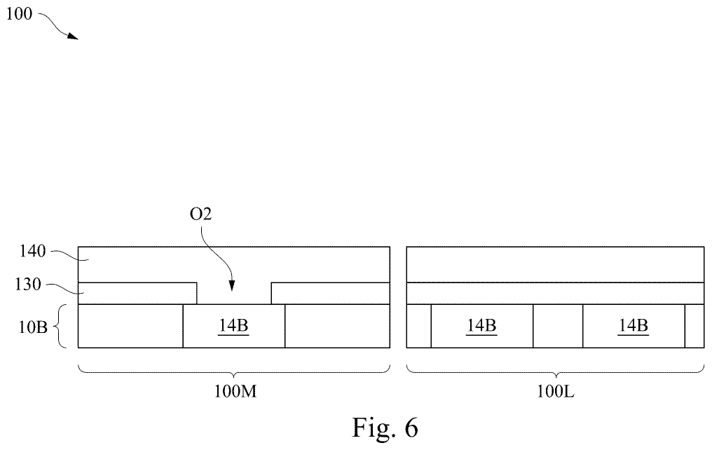

In FIG. 6, a conductive layer 140 is formed over the dielectric layer 130 using any acceptable deposition technique (e.g., CVD, ALD, PEALD, PECVD, PVD, ECP, electroless plating, or the like, or any combination thereof). In some embodiments, deposition process of the conductive layer 140 continues until the opening O2 in the dielectric layer 130 is overfilled with the conductive layer 140. In some embodiments, the conductive layer 140 includes a suitable conductive material to serve as a transistor gate. For example, the conductive layer 140 includes TaN, TiN, W, Al, polysilicon, combinations thereof, or the like.

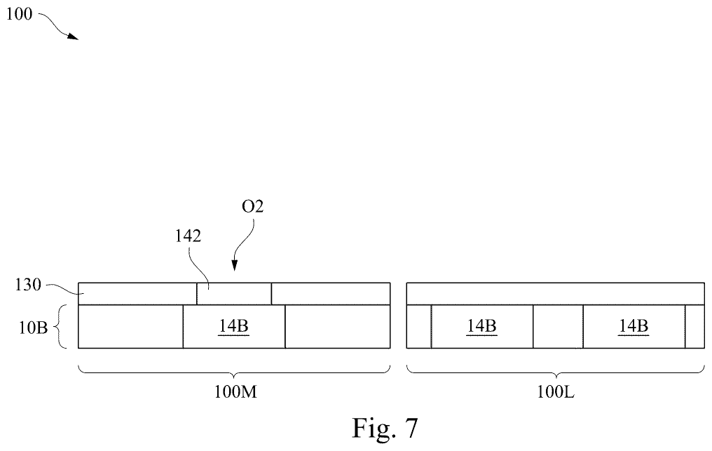

In FIG. 7, a planarization process (e.g., CMP) may be used to remove excess portions the metal layer 140 outside the opening O2 in the dielectric layer 130, while leaving a portion in the opening O2 to serve as a gate structure 142 of a BEOL transistor formed in subsequent processing. The gate structure 142 can be referred to as a BEOL transistor gate.

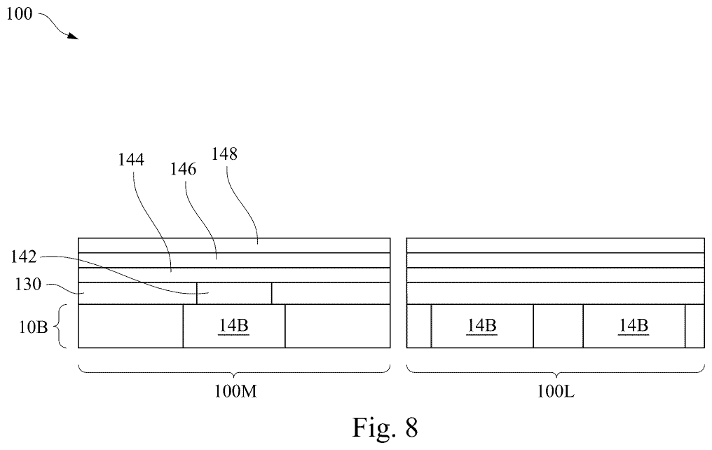

In FIG. 8, a gate dielectric layer 144, a channel layer 146, and a hard mask layer 148 are deposited in sequence over the BEOL transistor gate 142, by using acceptable deposition techniques (e.g., CVD, ALD, PEALD, PECVD, PVD, the like, or any combination thereof). In some embodiments, the gate dielectric layer 144 includes silicon oxide (SiO₂) and/or a high-k dielectric material. High-k gate dielectrics, as used and described herein, include dielectric materials having a high dielectric constant, for example, greater than that of thermal silicon oxide (˜3.9). The high-k dielectric material of the gate dielectric layer 144 may include hafnium oxide (HfO₂). Alternatively, the gate dielectric layer 144 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO) , barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitride (SiON), and combinations thereof.

In some embodiments, the channel layer 146 is a semiconductor layer formed of oxide semiconductor, such as indium gallium zinc oxide (IGZO), zinc oxide (ZnO), Indium Zinc Oxide (IZO), gallium zinc oxide (GZO), or the like. In some other embodiments, the channel layer 146 is formed of polysilicon. In some embodiments, the mask layer 148 is formed from a dielectric material, such as silicon nitride (SiNₓ) or other suitable dielectric materials. In some embodiments where the channel layer 146 is an n-type channel, it includes IGZO, ZnO, In₂O₃, SnO₂, or the like. In some embodiments where the channel layer 146 is a p-type channel, it includes NiO, Cu₂O, CuAlO₂, CuGaO₂, CuInO₂, SrCu₂O₂, SnO, or the like.

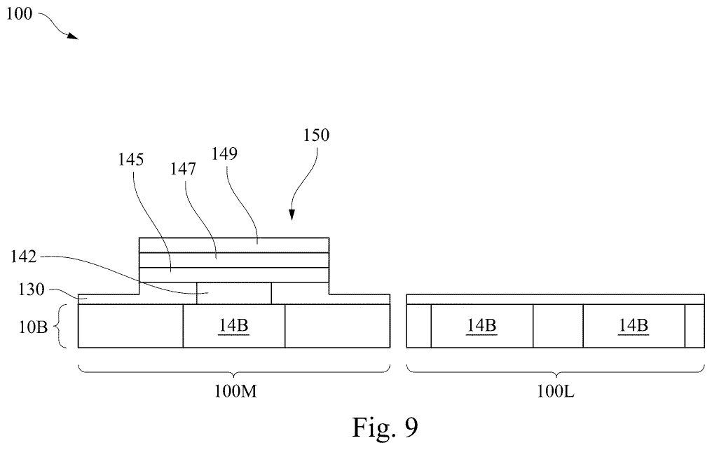

In FIG. 9, the mask layer 148, the channel layer 146 and the gate dielectric layer 144 are patterned in one or more etching processes to form a patterned gate dielectric layer 145, over the BEOL transistor gate 142, a patterned channel layer 147 over the patterned gate dielectric layer 145, and a patterned mask layer 149. The BEOL transistor gate 142 and the patterned channel layer 147 collectively act as a BEOL transistor 150. In some embodiments, the BEOL transistor 150 has a source/drain region electrically connected to an MTJ cell by using conductive vias and lines formed in subsequent processing. This configuration allows the BEOL transistor 150 to function as an access transistor for the MTJ cell. Compared to using a FEOL transistor (e.g., FinFET 104), which is directly formed on the substrate 102, as an access transistor, the BEOL transistor 150 offers a reduced distance to the MTJ cell. This shortened distance facilitates faster read and write operations, making it advantageous for high-speed memory applications. In some embodiments, as illustrated in FIG. 9, the one or more etching processes for forming the BEOL transistor 150 may also recess a portion of the dielectric layer 130 which laterally extends beyond the BEOL transistor 150. Therefore, the dielectric layer 130 has a larger thickness at a region directly below the gate dielectric layer 145 than at a region non-overlapping with the gate dielectric layer 145.

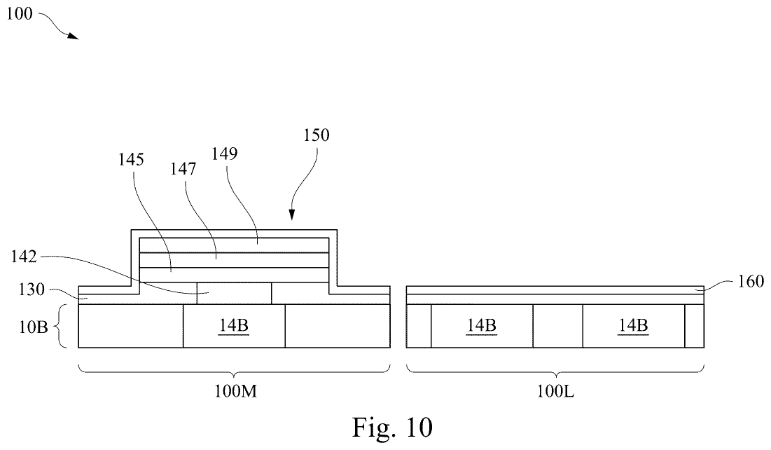

In FIG. 10, a dielectric layer 160 is formed over the BEOL transistor 150 and spanning the memory region 100M and the logic region 100L. In some embodiments, the dielectric layer 160 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the underlying dielectric layer 130.

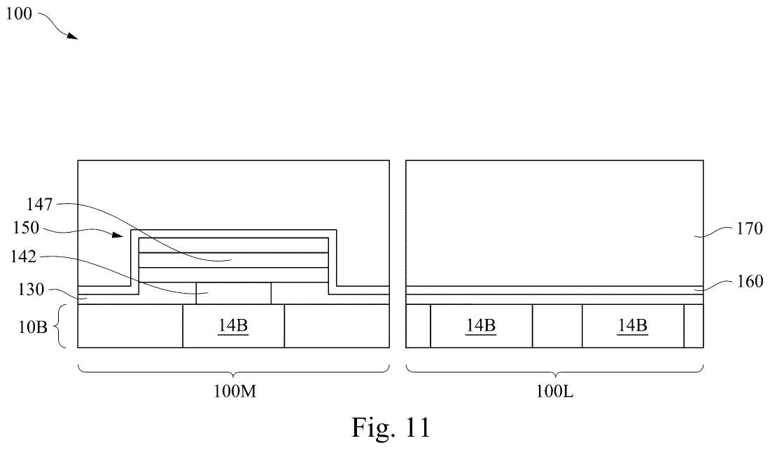

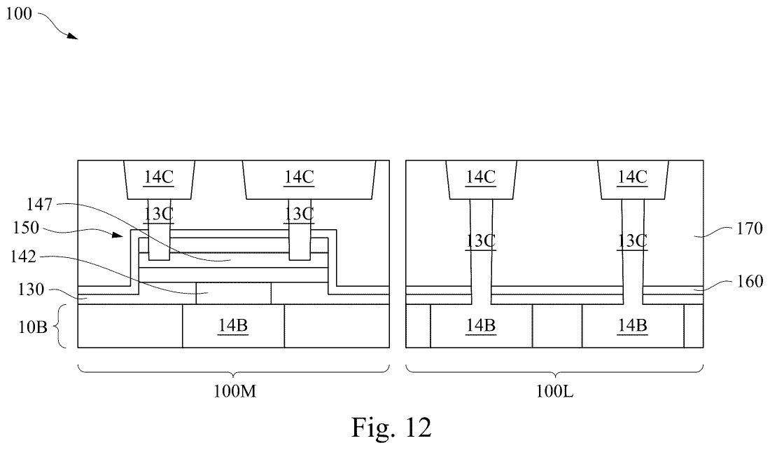

In FIG. 11, an IMD layer 170 is formed over the dielectric layer 160. In some embodiments, the IMD layer 170 is made of an extreme low-k (ELK) dielectric material with a dielectric constant (k) less than about 2.5. With geometric size shrinking as technology nodes advance to 7 nm and beyond, ELK dielectric material can be used to minimize device RC delay. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon dioxide (SiO₂). In some embodiments, ELK dielectric material is deposited by a plasma enhanced chemical vapor deposition (PECVD) process or by a spin coating process.

In FIG. 12, conductive vias 13C and conductive lines 14C are formed in the IMD layer 170. In some embodiments, a ppropriate photolithography and etching techniques (e.g., anisotropic RIE employing fluorocarbon chemistry) may be used to pattern the IMD layer 170 to form openings for vias and lines. Openings for vias 13C in memory region 100M are vertical holes extending through the IMD layer 170, the dielectric layer 160, the patterned mask 149 into the patterned channel layer 147. Openings for vias 13C in logic region 100L are vertical holes extending through the IMD layer 170, the dielectric layers 160 and 130 to the conductive lines 14B.

Several conductive materials may be deposited to fill the holes and trenches forming the conductive vias 13C and conductive lines 14C. In some embodiments, the conductive materials include, for example, TaN, TiN, W, Al, polysilicon, Ru, Co, Cu, combinations thereof, or the like. The openings may be first lined with a conductive diffusion barrier material and then completely filled with a conductive fill material deposited over the conductive diffusion barrier liner. In some embodiments, a thin conductive seed layer may be deposited over the conductive diffusion barrier liner to help initiate an electrochemical plating (ECP) deposition step that completely fills the openings with a conductive fill material.

The diffusion barrier conductive liner in the conductive vias 13C and conductive lines 14C comprises one or more layers of TaN, Ta, TiN, Ti, Co, or the like, or combinations thereof. The conductive fill layer in the conductive vias 13C and conductive lines 14C may comprise metals such as Cu, Al, W, Co, Ru, or the like, or combinations thereof, or multi-layers thereof. The conductive materials used in forming the conductive vias 13C and conductive lines 14C may be deposited by any suitable method, for example, CVD, PECVD, PVD, ALD, PEALD, ECP, electroless plating and the like. In some embodiments, the conductive seed layer may be of the same conductive material as the conductive fill layer and deposited using a suitable deposition technique (e.g., CVD, PECVD, ALD, PEALD, or PVD, or the like).

Any excess conductive material over the IMD layer 170 outside of the openings may be removed by a planarizing process (e.g., CMP) thereby forming a top surface comprising dielectric regions of IMD layer 170 that are substantially coplanar with conductive regions of the conductive lines 14C. The planarization step embeds the conductive vias 13C and conductive lines 14C into IMD layer 170, as illustrated in FIG. 12.

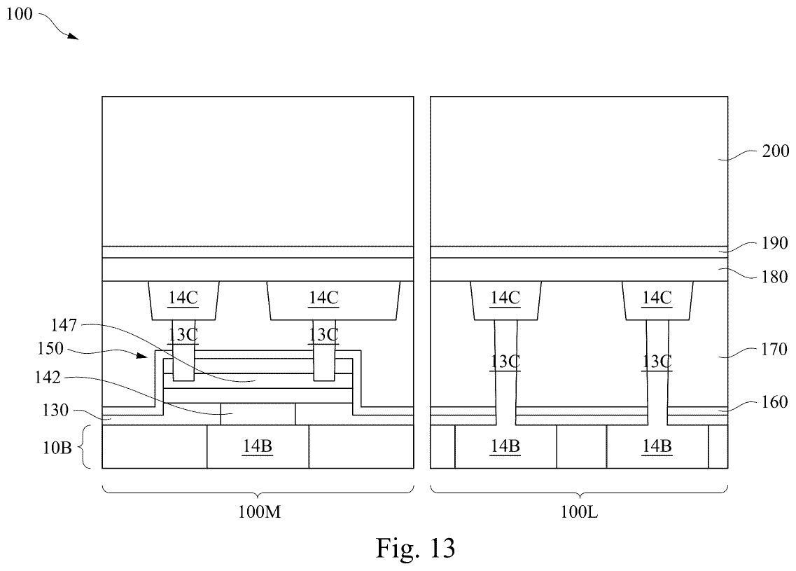

In FIG. 13, another dielectric layer (also referred to as a dielectric barrier layer (SBL)) 180 is formed spanning the memory region 100M and the logic region 100L. In some embodiments, the dielectric layer 210 may include one or more dielectric materials such as Si₃N₄, SiON, SiC, SiCN, or a combination thereof in various embodiments. The dielectric layer 180 may be formed by any suitable deposition process, such as spin coating, physical vapor deposition (PVD), chemical vapor deposition (CVD), the like, or a combination thereof.

Next, another dielectric layer 190 is formed over the dielectric layer 180 and spanning the memory region 100M and the logic region 100L. In some embodiments, the dielectric layer 190 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the underlying dielectric layer 180.

Next, another IMD layer 200 is formed over the dielectric layer 190. In some embodiments, the IMD layer 170 is made of an extreme low-k (ELK) dielectric material with a dielectric constant (k) less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon dioxide (SiO₂). In some embodiments, ELK dielectric material is deposited by a plasma enhanced chemical vapor deposition (PECVD) process or by a spin coating process.

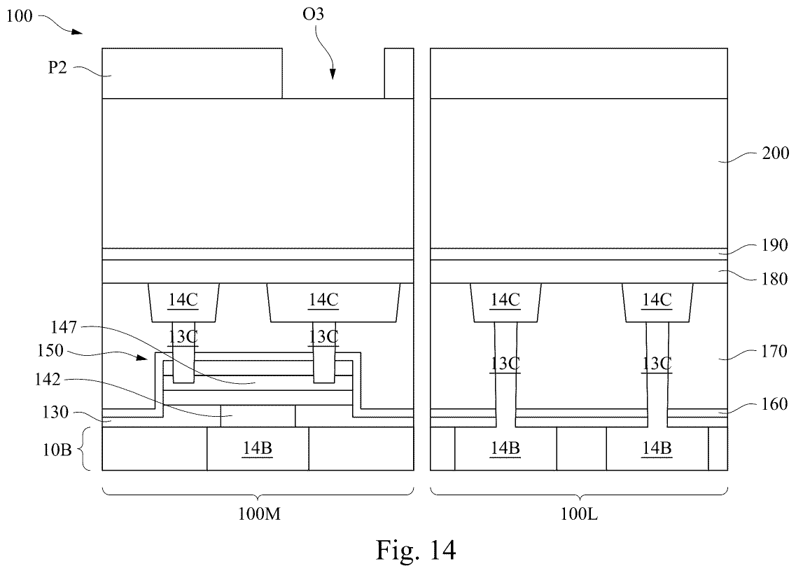

In FIG. 14, a patterned mask P2 is formed over the IMD layer 120. In some embodiments, the patterned mask P2 is a patterned photoresist formed using suitable photolithography process. In an example photolithography process, photoresist material is irradiated (exposed) and developed to remove portions of the photoresist material. In greater detail, a photomask or reticle (not shown) may be placed above the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material. A developer may be used to remove either the exposed or unexposed portions of the photoresist material depending on whether a positive or negative resist is used, leaving a patterned photoresist mask P2 over the IMD layer 200, with an opening O3 exposing a portion of the IMD layer 200.

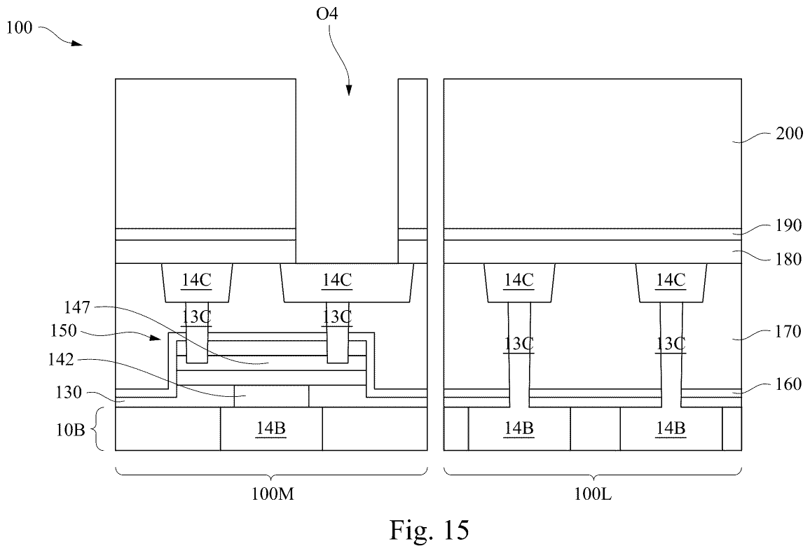

In FIG. 15, the IMD layer 200 patterned in an etching process by using the patterned mask P2 as an etch mask, creating an opening O4 extending through the IMD layer 200, the dielectric layers 190 and 180 to expose a conductive line 14C, which is electrically connected to a source/drain region of the BEOL transistor 150. The IMD layer 200 can be patterned by using suitable etching techniques, such as wet etching, dry etching, or combinations thereof. After forming the opening O4 in the dielectric IMD layer 200, the patterned mask P2 can be removed, for example, using a plasma ash process. In some embodiments, a plasma ash process is performed such that the temperature of the photoresist is increased until the photoresist experiences a thermal decomposition and may be removed. However, any other suitable process, such as a wet strip, may be utilized.

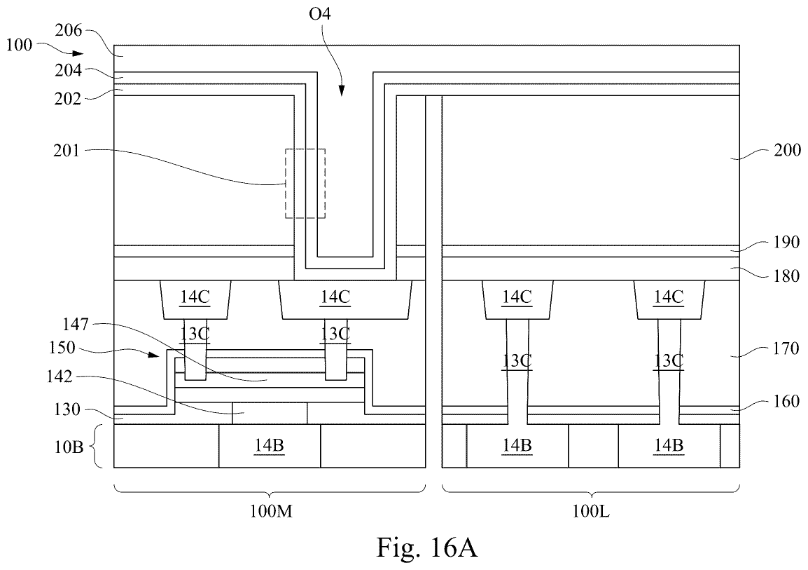

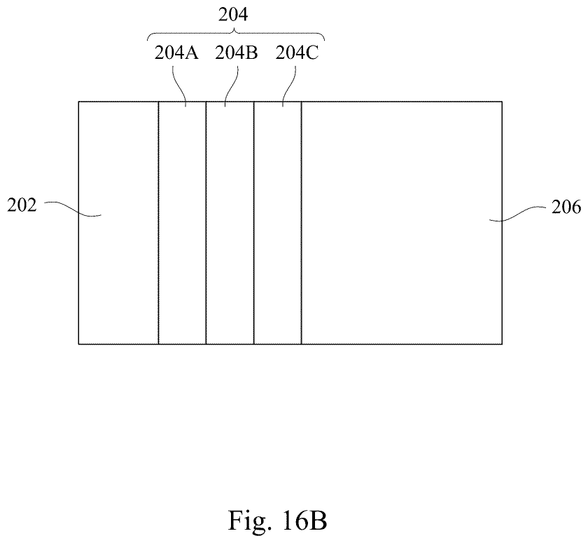

In FIG. 16A, a bottom electrode layer 202, an MTJ layer 204, and a top electrode layer 206 are deposited in sequence into the opening O4 in the IMD layer 200. In some embodiments where the opening has an aspect ratio (i.e., ratio of opening depth to opening width) in a range from about 0.5 to about 2.5, the bottom electrode layer 202, the MTJ layer 204, and the top electrode layer 206 can be deposited using a PVD process. In some embodiments where the opening has an aspect ratio (i.e., ratio of opening depth to opening width) greater than about 2.5, the bottom electrode layer 202, the MTJ layer 204, and the top electrode layer 206 can be deposited using an ALD process. In some embodiments, the opening O4 has a top width wider than a bottom width of the opening O4, which facilitates depositing the bottom electrode layer 202, the MTJ layer 204, and the top electrode layer 206 into the opening O4.

In some embodiments, the bottom electrode 202 is formed over the conductive line 14C and the IMD layer 200. The bottom electrode layer 202 is formed of a conductive material such as titanium (Ti), tantalum (Ta), aluminum (Al), tungsten (W), platinum (Pt), nickel (Ni), chromium (Cr), ruthenium (Ru), nitrides thereof, combinations or multiple layers thereof, or the like. The bottom electrode layer 202 may be deposited by a conformal deposition process, such as CVD, PVD, ALD, electrochemical plating, electroless plating, or the like.

In some embodiments, the MTJ layer 204 includes MgO serving as a tunnel barrier material, and Fe mixed with Co, B, or Ni serving as ferromagnetic materials. In some embodiments, the MTJ layer 204 is a multilayered film stack including, for example, an outer magnetic layer 204A, a tunnel barrier layer 204B and an inner magnetic layer 204C formed in sequence over the bottom electrode layer 202. The outer magnetic layer 204A, the tunnel barrier layer 204B and the inner magnetic layer 204C collectively form a magnetic tunnel junction (MTJ) and are thus in combination referred to as an MTJ layer 204 in some embodiments of the present disclosure, as illustrated in FIG. 16B, which is a zoomed-in view of a region 201 of FIG. 16A.

In some embodiments, the outer magnetic layer 204 is a multi-layered structure that includes an anti-ferromagnetic material (AFM) layer over the bottom electrode layer 202 and a ferromagnetic pinned layer over the AFM layer. In the anti-ferromagnetic material (AFM) layer, magnetic moments of atoms (or molecules) align in a regular pattern with magnetic moments of neighboring atoms (or molecules) in opposite directions. A net magnetic moment of the AFM layer is zero. In certain embodiments, the AFM layer includes platinum manganese (PtMn). In some embodiments, the AFM layer includes iridium manganese (IrMn), rhodium manganese (RhMn), or iron manganese (FeMn). An exemplary formation method of the AFM layer includes sputtering, PVD, ALD or the like.

The ferromagnetic pinned layer in the outer magnetic layer 204A forms a permanent magnet and exhibits strong interactions with magnets. A direction of a magnetic moment of the ferromagnetic pinned layer can be pinned by the anti-ferromagnetic material (AFM) layer and is not changed during operation of a resulting MTJ stack fabricated from the MTJ layer 204, e.g., during write operations of resultant MRAM cells. In certain embodiments, the ferromagnetic pinned layer includes cobalt-iron-boron (CoFeB). In some embodiments, the ferromagnetic pinned layer includes CoFeTa, NiFe, Co, CoFe, CoPt, or the alloy of Ni, Co and Fe. An exemplary formation method of the ferromagnetic pinned layer includes sputtering, PVD or ALD. In some embodiments, the ferromagnetic pinned layer includes a multi-layered structure.

The tunnel barrier layer 204B is formed over the outer magnetic layer 204A. The tunnel barrier layer 204B can also be referred to as a tunneling layer, which is thin enough such that electrons are able to tunnel through the tunnel barrier layer when a biasing voltage is applied to a resulting MTJ stack fabricated from the MTJ layer 204. In certain embodiments, the tunnel barrier layer 204B includes magnesium oxide (MgO), aluminum oxide (Al₂O₃), aluminum nitride (AlN), aluminum oxynitride (AlON), hafnium oxide (HfO₂) or zirconium oxide (ZrO₂). An exemplary formation method of the tunnel barrier layer 204B includes sputtering, PVD, ALD or the like.

The inner magnetic layer 204C is formed over the tunnel barrier layer 204B. The inner magnetic layer 204C is a ferromagnetic free layer in some embodiments. More specifically, a direction of a magnetic moment of the inner magnetic layer 204C is not pinned because there is no anti-ferromagnetic material in the inner magnetic layer 204C. Therefore, the magnetic orientation of this layer is adjustable, thus the layer is referred to as a free layer. In some embodiments, the direction of the magnetic moment of the inner magnetic layer 204C is free to rotate parallel or anti-parallel to the pinned direction of the magnetic moment of the ferromagnetic pinned layer in the inner magnetic layer 204A. The inner magnetic layer 204C may include a ferromagnetic material similar to the material in the ferromagnetic pinned layer in the first magnetic layer 151. Since the inner magnetic layer 204C has no anti-ferromagnetic material while the outer magnetic layer 204A has an anti-ferromagnetic material therein, the lower and inner magnetic layers 204A and 204C have different materials. In certain embodiments, the inner magnetic layer 204C includes cobalt, nickel, iron or boron. An exemplary formation method of the inner magnetic layer 204C includes sputtering, PVD, ALD or the like. Although in the depicted embodiment the ferromagnetic free layer 204C is the innermost layer in the MTJ layer 204, the MTJ layer 204 further includes an additional MgO layer over the free layer 204C, and a capping layer (e.g., TaN or TiN) over the additional MgO layer in some other embodiments.

The electrical resistance through the MTJ layer 204 varies depending on magnetic orientations of the outer magnetic layer 204A and the inner magnetic layer 204C, and this phenomenon is used to store data in the resulting MRAM cells. The outer magnetic layer 204A may be a permanent magnet, which is set to a fixed polarity, while the magnetic polarity of the inner magnetic layer 204C can be changed by application of an electrical field. When the magnetization direction of the inner magnetic layer 204C matches (i.e., parallel with) the magnetization direction of the outer magnetic layer 204A, the MRAM cell is in the low-resistance state. When the magnetization direction of the inner magnetic layer 204C is opposite (i.e., anti-parallel with) the magnetization direction of the outer magnetic layer 204A, the MRAM cell is in the high-resistance state.

In FIGS. 17A and 17B, a planarization process (e.g., CMP) is be used to remove excess portions of the bottom electrode layer 202, the MTJ layer 204, and the top electrode layer 206 outside the opening O4 in the IMD layer 200, while leaving a portion of the bottom electrode layer 202 in the opening O4 to serve as a bottom electrode, a portion of the MTJ layer 204 in the opening O4 to serve as an MTJ stack 214, a portion of the top electrode layer 206 in the opening O4 to serve as a top electrode. The bottom electrode 212, the MTJ stack 214, and the top electrode 216 collectively serve as an MTJ cell 211, with the bottom electrode 212 electrically connected to a source/drain region in the patterned channel layer 147 of the BEOL transistor 150. In some embodiments, the MTJ cell 211 is also referred to as a memory cell, with the MTJ stack 214 serving as a resistance switching layer or element, which has two states of resistance depending on the magnetization direction of free layer in the MTJ stack 214.

In FIG. 17A, in some embodiments, the MTJ stack 214 has a lateral dimension W1 and a vertical dimension H1 greater than the lateral dimension W1. This vertical elongation of the MTJ stack 214 effectively increases the MTJ junction area in the vertical direction, thereby mitigating magnetoresistance variations and enhancing the lifespan of MTJ cells 211 without compromising the cell area. In some embodiments, a ratio of the vertical dimension H1 to the lateral dimension W1 of the MTJ stack 214 is greater than 2:1, 3:1, 5:1, 6:1, 7:1, 8:1, 9:1, or 10:1, depending on a ratio of target MTJ junction area and pitch of MTJ cells 211. In some embodiments, the vertical dimension H1 of the MTJ stack 214 is higher than a vertical dimension H2 of the BEOL transistor 150, which is measured from a bottom surface of the gate structure 142 to a top surface of the patterned channel layer 147. In some embodiments, the lateral dimension W1 of the MTJ stack 214 is less than a lateral dimension W2 of the BEOL transistor 150, which is measured between opposite side surfaces of the patterned channel layer 147. As a result, the MTJ stack 214 has a height-to-width ratio greater than a height-to-width ratio of the BEOL transistor 150.

In some embodiments, as illustrated in the top view of FIG. 17B, the MTJ cell 211 vertically overlaps with the BEOL transistor 150, especially a source/drain region 150S/D of the BEOL transistor 150, which is a partial region in the patterned channel layer 147 extending beyond the gate structure 142. The MTJ cell 211 and the BEOL transistor 150 have overlapping footprints on the substrate 102. In this way, the resultant MRAM cell can have a reduced footprint on the substrate 102, thereby increasing the memory density on the IC structure 100. The memory density on the IC structure 100 refers to the amount of data storage capacity that can be packed into a given physical area of the IC structure 100. This overlapping configuration not only improves the use of available space but also enhances the performance characteristics of the MRAM cell. By reducing the distance between the MTJ cell 211 and the BEOL transistor 150, the electrical connectivity is improved, leading to faster read and write operations. Additionally, this design can reduce parasitic capacitance and resistance, facilitating high-speed memory operations. The integration of the MTJ cell 211 with the BEOL transistor 150 in such a compact manner can also facilitate better thermal management, as the heat generated during operation can be more efficiently dissipated across the smaller footprint.

In some embodiments where the opening O4 has a top width wider than a bottom width of the opening O4, as illustrated in FIG. 17C, the top electrode 216 can have an inverted trapezoid pattern with a bottom width and a top width greater than the bottom width. The MTJ stack 124 and the bottom electrode 212 have tapered sidewalls.

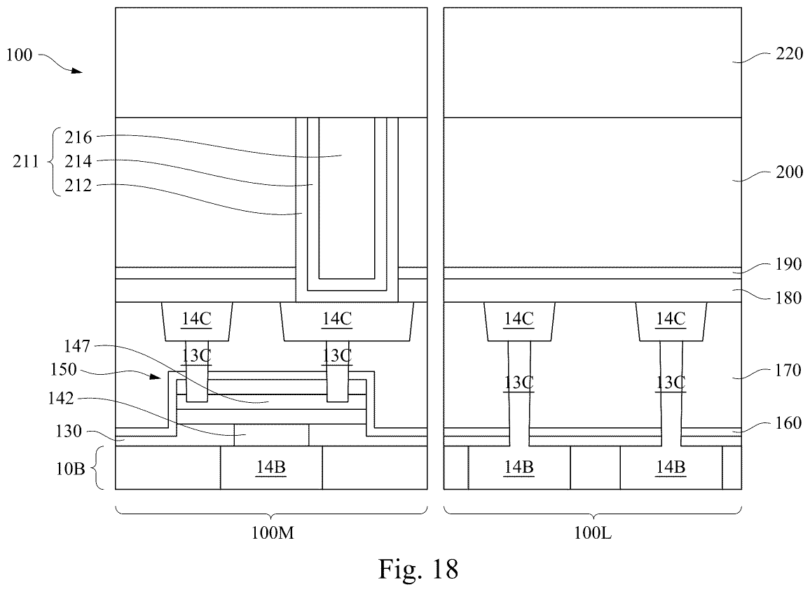

Next, in FIG. 18, another IMD layer 220 is formed over the IMD layer 220 and the MTJ cell 211. In some embodiments, the IMD layer 220 is made of an extreme low-k (ELK) dielectric material with a dielectric constant (k) less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon dioxide (SiO₂). In some embodiments, ELK dielectric material is deposited by a plasma enhanced chemical vapor deposition (PECVD) process or by a spin coating process.

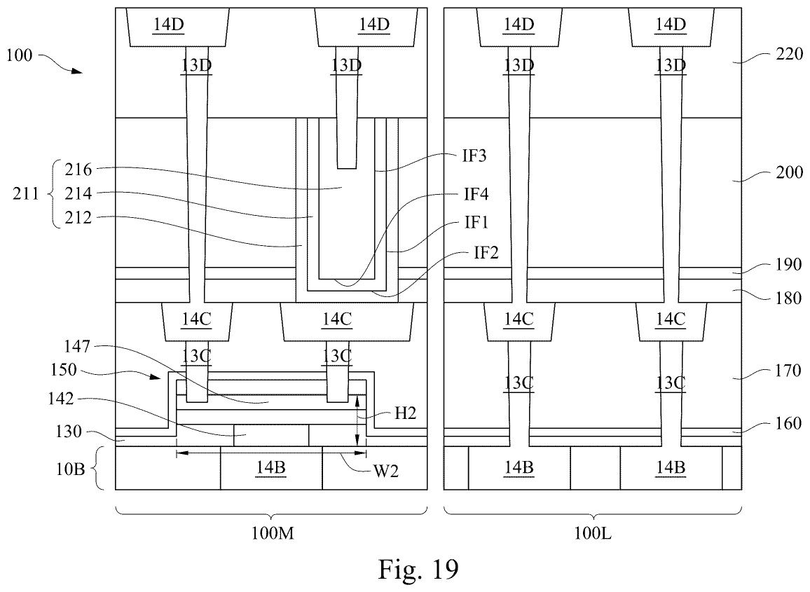

In FIG. 19, conductive vias 13D and conductive lines 14D are formed in the IMD layer 220. In some embodiments, a ppropriate photolithography and etching techniques (e.g., anisotropic RIE employing fluorocarbon chemistry) may be used to pattern the IMD layers 220, 200, the dielectric layers 190 and 180 to form openings for vias and lines. Openings for vias 13D in memory region 100M include a vertical hole extending through the IMD layer 220 into the top electrode 216 of the MTJ cell 211, and a vertical hole extending through the IMD layers 220, 200, and the dielectric layers 190, 180 to the conductive line 14C. Openings for vias 13D in logic region 100L are vertical holes extending through the IMD layers 220, 200, the dielectric layers 190 and 130 to the conductive lines 14C.

Several conductive materials may be deposited to fill the holes and trenches forming the conductive vias 13D and conductive lines 14D. The openings may be first lined with a conductive diffusion barrier material and then completely filled with a conductive fill material deposited over the conductive diffusion barrier liner. In some embodiments, a thin conductive seed layer may be deposited over the conductive diffusion barrier liner to help initiate an electrochemical plating (ECP) deposition step that completely fills the openings with a conductive fill material.

The diffusion barrier conductive liner in the conductive vias 13D and conductive lines 14D comprises one or more layers of TaN, Ta, TiN, Ti, Co, or the like, or combinations thereof. The conductive fill layer in the conductive vias 13C and conductive lines 14C may comprise metals such as Cu, Al, W, Co, Ru, or the like, or combinations thereof, or multi-layers thereof. The conductive materials used in forming the conductive vias 13D and conductive lines 14D may be deposited by any suitable method, for example, CVD, PECVD, PVD, ALD, PEALD, ECP, electroless plating and the like. In some embodiments, the conductive seed layer may be of the same conductive material as the conductive fill layer and deposited using a suitable deposition technique (e.g., CVD, PECVD, ALD, PEALD, or PVD, or the like).

Any excess conductive material over the IMD layer 220 outside of the openings may be removed by a planarizing process (e.g., CMP) thereby forming a top surface comprising dielectric regions of IMD layer 220 that are substantially coplanar with conductive regions of the conductive lines 14D. The planarization step embeds the conductive vias 13D and conductive lines 14D into IMD layer 220, as illustrated in FIG. 19.

In some embodiments, as illustrated in FIG. 19, the MTJ layer 214 forms a first interface with the bottom electrode 212, wherein the first interface comprises a first portion IF1 extending in a vertical direction toward the substrate and a second portion IF2 extending in a lateral direction different from the vertical direction. The first portion IF1 of the first interface is larger than the second portion IF2 of the first interface. In the cross-sectional view as illustrated in FIG. 19, a ratio of a length of the first portion IF1 to a length of the second portion IF2 is greater than a height-to-width ratio of the BEOL transistor 150 (i.e., the ratio of vertical dimension H2 to lateral dimension W2 of the BEOL transistor 150). The MTJ layer 214 forms a second interface with the top electrode 216. The second interface comprises a third portion IF3 extending in the vertical direction toward the substrate and a fourth portion IF4 extending in the lateral direction, wherein the third portion IF3 of the second interface is larger than the fourth portion IF4 of the second interface.

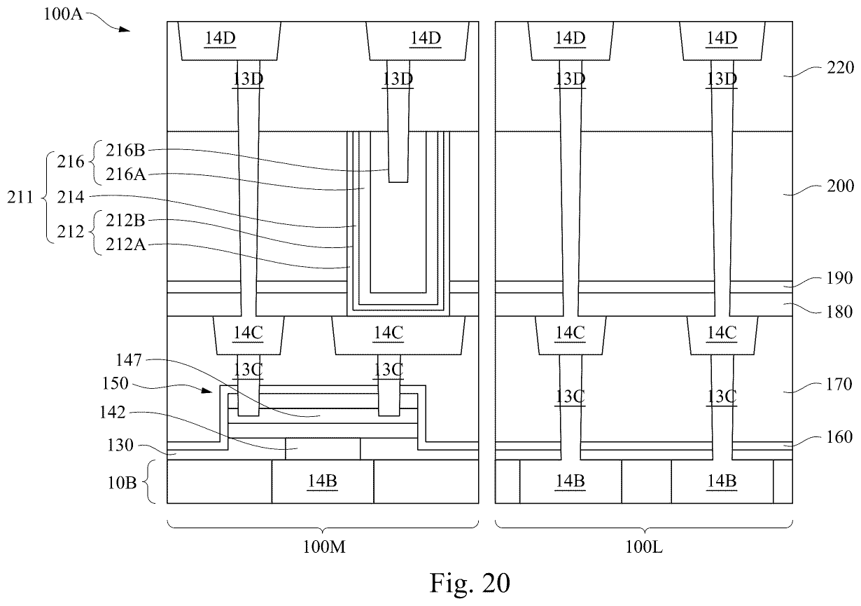

FIG. 20 illustrates a cross-sectional view of another example IC structure 100A in accordance with some embodiments of the present disclosure. The IC structure 100A includes substantially the same structure as the IC structure 100A illustrated in FIG. 19, except that the bottom electrode 212 and the top electrode 216 are both multilayered electrodes. In particular, the bottom electrode 212 is a dual-layer electrode including a first metal layer 212A and a second metal layer 212B disposed over the first metal layer 212A. The first metal layer 212A and the second metal layer 212B are formed of different metal materials. For example, the first metal layer 212A may include a diffusion barrier metal such as titanium nitride or tantalum nitride, and the second metal layer 212B may include a metal having a lower resistance than the first metal layer 212A. Similarly, the top electrode 216 includes a first metal layer 216A and a second metal layer 216B disposed over the first metal layer 216A. The first metal layer 216A and the second metal layer 216B are formed of different metal materials.

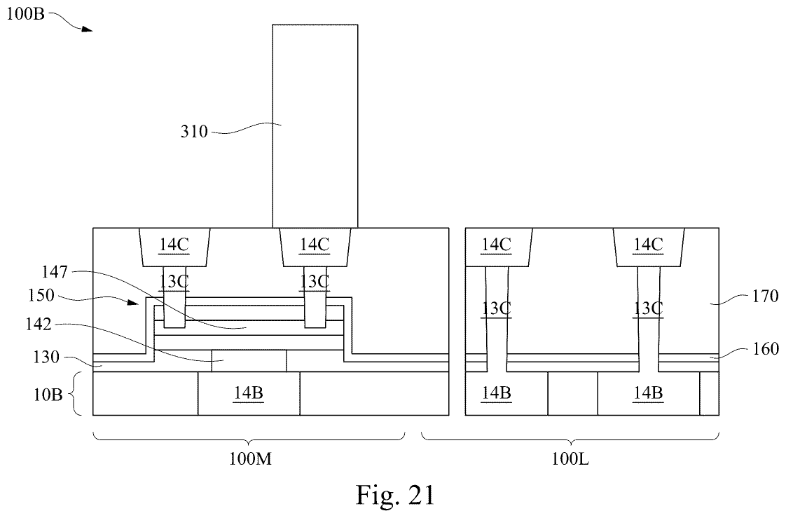

FIGS. 21-24 illustrate cross-sectional views of intermediate stages in formation of an example integrated circuit structure 100B having one or more MRAM cells in accordance with some embodiments of the present disclosure. The IC structure 100B in FIG. 21 includes substantially the same structure as the IC structure 100A illustrated in FIG. 12, except that a bottom electrode 310 is formed over the conductive line 14C. In some embodiments, the bottom electrode 310 is formed by, for example, depositing a metal layer globally over the memory region 100M and the logic region 100L, followed by patterning the metal layer into the bottom electrode 310 by using suitable photolithography and etching techniques. In some embodiments, the bottom electrode 310 is formed of a conductive material such as titanium (Ti), tantalum (Ta), aluminum (Al), tungsten (W), platinum (Pt), nickel (Ni), chromium (Cr), ruthenium (Ru), nitrides thereof, combinations or multiple layers thereof, or the like.

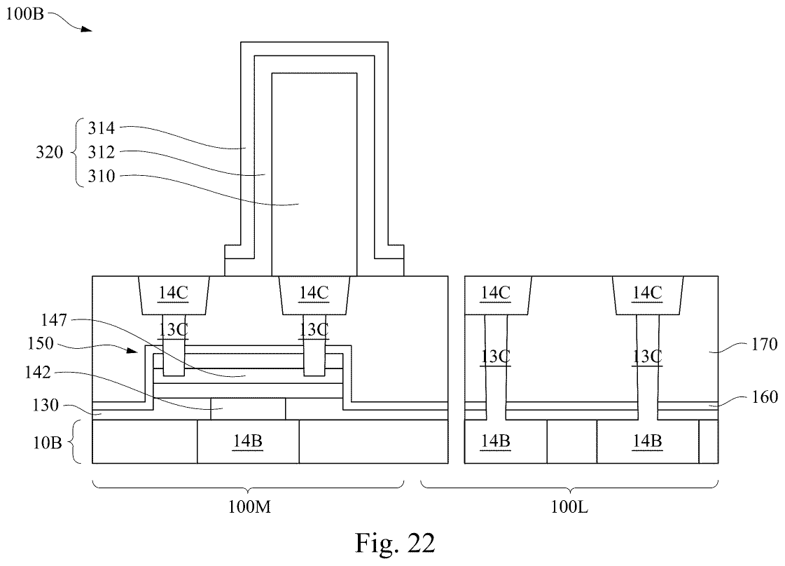

In FIG. 22, an MTJ stack 312 is formed over the bottom electrode 310, and a top electrode 314 is formed over the MTJ stack 312. In some embodiments, the MTJ stack 312 and the top electrode 314 are formed by, for example, depositing in sequence an MTJ layer and a top electrode layer spanning the memory region 100M and the logic region 100L, followed by patterning the MTJ layer and the top electrode layer into the MTJ stack 312 and the top electrode 314 by using suitable photolithography and etching techniques. The bottom electrode 310, the MTJ stack 312 and the top electrode 314 are collectively referred to as an MTJ cell 320. Materials of the MTJ layer and top electrode layer can be the same as that of the MTJ layer 204 and the top electrode layer 206 described previously with respect to FIG. 16A, and thus they are not repeated for the sake of brevity.

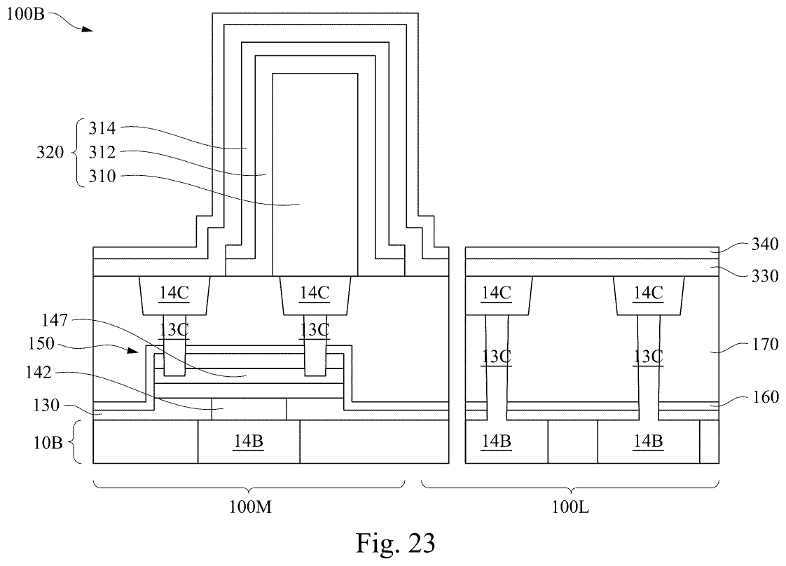

In FIG. 23, dielectric layers 330 and 340 are formed in sequence over the MTJ cell 320 and the IMD layer 170. In some embodiments, the dielectric layer 330 is also referred to a dielectric barrier layer (SBL) and may include one or more dielectric materials such as Si₃N₄, SiON, SiC, SiCN, or a combination thereof in various embodiments. In some embodiments, the dielectric layer 340 is formed over the dielectric layer 330 and spanning the memory region 100M and the logic region 100L. In some embodiments, the dielectric layer 340 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the underlying dielectric layer 330.

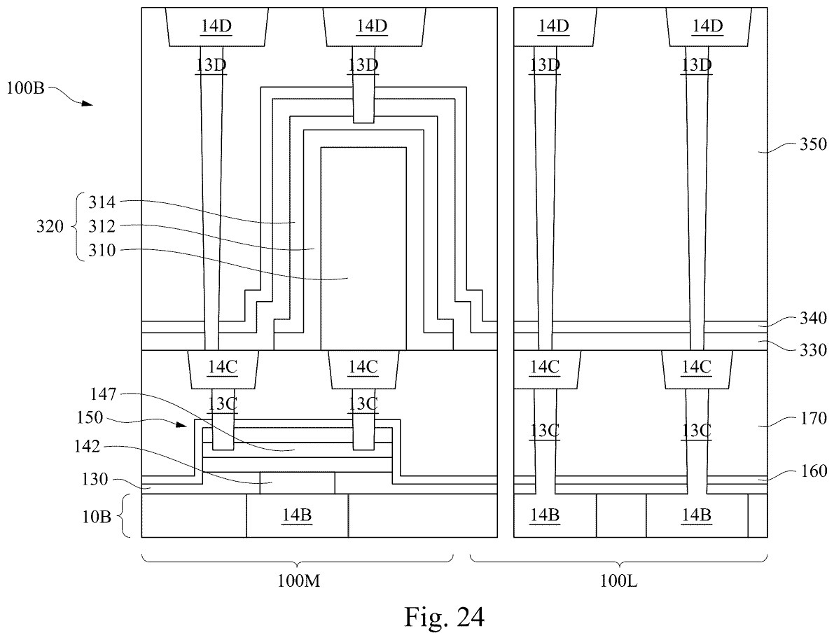

In FIG. 24, an IMD layer 200 is formed over the dielectric layer 340. In some embodiments, the IMD layer 200 is made of an extreme low-k (ELK) dielectric material with a dielectric constant (k) less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon dioxide (SiO₂). In some embodiments, ELK dielectric material is deposited by a plasma enhanced chemical vapor deposition (PECVD) process or by a spin coating process.

Next, conductive vias 13D and conductive lines 14D are formed in the IMD layer 350. In some embodiments, appropriate photolithography and etching techniques (e.g., anisotropic RIE employing fluorocarbon chemistry) may be used to pattern the IMD layer 350, the dielectric layers 340 and 330 to form openings for vias and lines. Openings for vias 13D in memory region 100M include a vertical hole extending through the IMD layer 350 into the top electrode 314 of the MTJ cell 320, and a vertical hole extending through the IMD layer 350, and the dielectric layers 340, 330 to the conductive line 14C. Openings for vias 13D in logic region 100L are vertical holes extending through the IMD layer 350, the dielectric layers 340 and 330 to the conductive lines 14C.

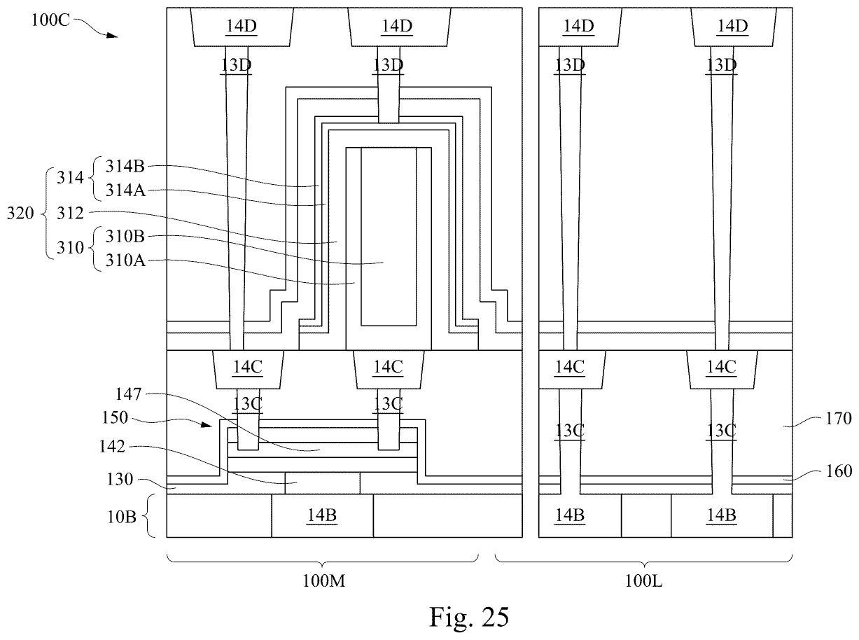

FIG. 25 illustrates a cross-sectional view of another example IC structure 100C in accordance with some embodiments of the present disclosure. The IC structure 100C includes substantially the same structure as the IC structure 100B illustrated in FIG. 24, except that the bottom electrode 310 and the top electrode 314 are both multilayered electrodes. In particular, the bottom electrode 310 is a dual-layer electrode including a first metal layer 310A and a second metal layer 310B disposed over the first metal layer 310A. The first metal layer 310A and the second metal layer 310B are formed of different metal materials. For example, the first metal layer 310A may include a diffusion barrier metal such as titanium nitride or tantalum nitride, and the second metal layer 310B may include a metal having a lower resistance than the first metal layer 310A. Similarly, the top electrode 314 includes a first metal layer 314A and a second metal layer 314B disposed over the first metal layer 314A. The first metal layer 314A and the second metal layer 314B are formed of different metal materials.

In some embodiments, the dual-layer bottom electrode 310 is formed by, for example, forming a sacrificial dielectric layer with an opening in the memory region 100M, depositing in sequence the first metal layer 310A and the second metal layer 310B in the opening, removing portions of the first and second metal layers 310A, 310B outside the opening by using a CMP process, followed by removing the sacrificial dielectric layer. In some embodiments, the dual-layer top electrode 314 is formed by, for example, depositing in sequence the first metal layer 314A and the second metal layer 314B over the bottom electrode 310, followed by patterning the first and second metal layers 314A, 314B by using suitable photolithography and etching processes.

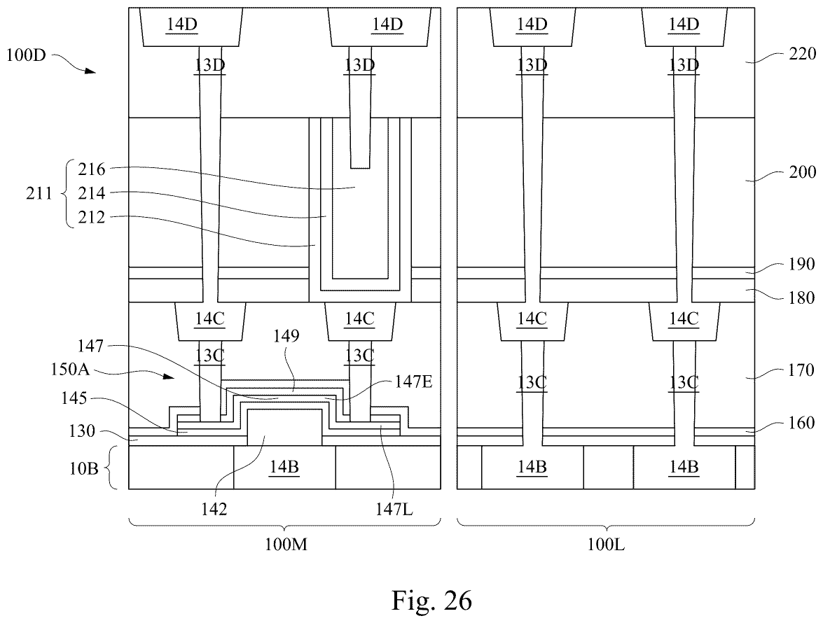

FIG. 26 illustrates a cross-sectional view of another example IC structure 100D in accordance with some embodiments of the present disclosure. The IC structure 100D includes substantially the same structure as the IC structure 100 illustrated in FIG. 19, except that the BEOL transistor 150A has a different cross-sectional profile than the BEOL transistor 150 illustrated in FIG. 19. In some embodiments, after the step illustrated in FIG. 7, the dielectric layer 130 is recessed by a selective etching back process such that the BEOL gate 142 protrudes from a top surface of the recessed dielectric layer 130. As a result, the gate dielectric layer 145, the channel layer 147, and the hard mask layer 149 can have inverted U-shaped profiles that wrap around at least three sides of the protruding portion of the BEOL gate 142, due to these layers being deposited on the protruding portion of the BEOL gate 142. This configuration can improve driving capability of the BEOL transistor 150A.

In some embodiments, as illustrated in FIG. 26, the channel layer 147 has lower portions L laterally surrounding sidewalls of the BEOL gate 142, and an elevated portion 147E elevated above a top surface of the BEOL gate 142. The conductive vias 13C are disposed over source/drain regions in the lower portions L of the channel layer 147. Such configuration can reduce leakage current due to an increased distance between conductive vias 13C and the BEOL gate 142.

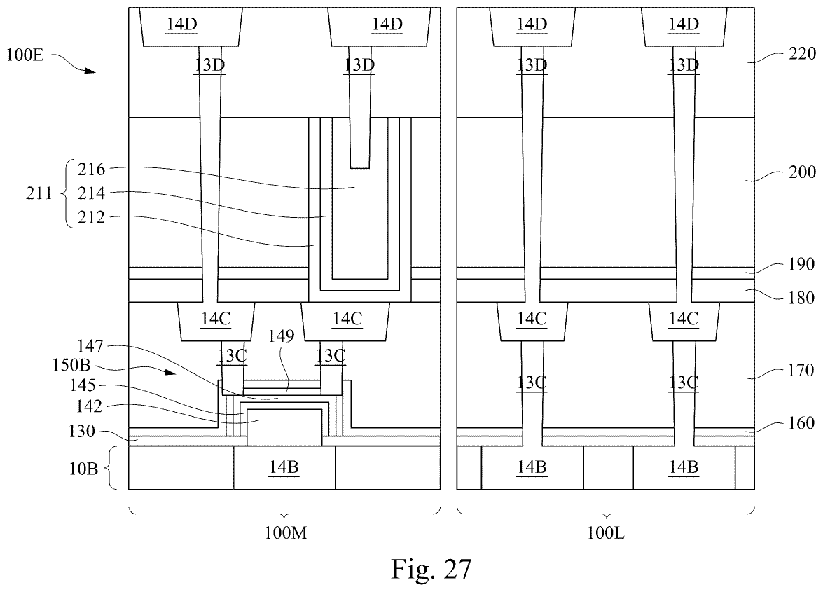

FIG. 27 illustrates a cross-sectional view of another example IC structure 100E in accordance with some embodiments of the present disclosure. The IC structure 100E includes substantially the same structure as the IC structure 100D illustrated in FIG. 26, except that the BEOL transistor 150B has a different cross-sectional profile than the BEOL transistor 150A illustrated in FIG. 26. For example, as illustrated in FIG. 27, the gate dielectric layer 145, the channel layer 147, and the mask layer 149 do not extend horizontally beyond sidewalls of the BEOL gate 142.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that MTJ junction area can be increased without increasing the MTJ cell footprint. Another advantage is that magnetoresistance variations can be mitigated due to the increased MTJ junction area. Another advantage is that the lifespan and retention time of MTJ cells can be improved due to the increased MTJ junction area.

In some embodiments, a method includes following steps. A metal interconnect structure (e.g., conductive vias 13C and lines 14C) is formed within a first dielectric layer (e.g., IMD layer 170) over a substrate. A second dielectric layer (e.g., IMD layer 200) is formed over the first metal interconnect structure. An opening (e.g., opening O4) is etched in the second dielectric layer and over a portion of the first metal interconnect structure. A bottom electrode layer (e.g., layer 202) is deposited in the opening. A magnetic tunnel junction (MTJ) layer (e.g., layer 204) is deposited in the opening and over the bottom electrode layer. A top electrode layer (e.g., layer 206) is deposited in the opening and over the MTJ layer. Portions of the top electrode layer, the MTJ layer, the bottom electrode layer outside the opening in the second dielectric layer are removed to form a top electrode (e.g., top electrode 216), an MTJ stack (e.g., MTJ stack 214), and a bottom electrode (e.g., bottom electrode 212) within the opening in the second dielectric layer. In some embodiments, the top electrode layer is deposited until the opening in the second dielectric layer is overfilled with the top electrode layer. In some embodiments, the opening O4 in the second dielectric layer has a width and a depth greater than the width. In some embodiments, the top electrode 216 has a width and a height greater than the width. In some embodiments, the MTJ stack 214 forms an interface with the top electrode 216, and the interface extends further in a vertical direction than in a lateral direction. In some embodiments, the MTJ stack 214 forms an interface with the bottom electrode 212, and the interface extends further in a vertical direction than in a lateral direction. In some embodiments, the portions of the top electrode layer, the MTJ layer, the bottom electrode layer outside the opening in the second dielectric layer are removed in a chemical mechanical polish (CMP) process. In some embodiments, the method further comprises forming a transistor (e.g., BEOL transistor 150, 150A, or 150B) prior to forming the metal interconnect, the transistor having a gate (e.g., BEOL gate 142) over the substrate, and a channel layer (e.g., channel layer 147) over the gate. In some embodiments, the channel layer wraps around at least three sides of the gate.

In some embodiments, a method includes following steps. A first transistor (e.g., FinFET 104) is formed over a substrate. A first interconnect structure (e.g., conductive lines 14B) is formed over the first transistor. A second transistor (e.g., BEOL transistor 150) is formed over the first interconnect structure. The second transistor includes a gate structure and a channel layer over the gate structure. A second interconnect structure (e.g., conductive lines 14C) is formed over the second transistor. A memory cell (e.g., MTJ cell 211 or 320) is formed over the second interconnect structure. The memory cell is electrically connected to the second transistor by using the second interconnect structure. The channel layer of the second transistor is below the memory cell and above the gate structure of the second transistor. In some embodiments, the memory cell comprises an MTJ layer (e.g., MTJ layer 214 or 312) between two electrodes, the MTJ layer extends further in a vertical direction than in a lateral direction. In some embodiments, the memory cell comprises an MTJ layer (e.g., MTJ layer 214) between two electrodes (e.g., bottom and top electrodes 212, 216), and the MTJ layer has a U-shaped cross-sectional profile. In some embodiments, the memory cell comprises an MTJ layer (e.g., MTJ layer 312) between two electrodes (e.g., bottom and top electrodes 310, 314), and the MTJ layer has an inverted U-shaped cross-sectional profile. In some embodiments, forming the memory cell comprises forming a dielectric layer (e.g., IMD layer 200) over the first interconnect structure, forming an opening (e.g., opening O4) in the dielectric layer, after forming the opening in the dielectric layer, forming the memory cell (e.g., MTJ cell 211) in the opening in the dielectric layer. In some embodiments, forming the memory cell comprises forming a bottom electrode (e.g., bottom electrode 310) over the first interconnect structure, forming an MTJ layer (e.g., MTJ layer 312) wrapping around the bottom electrode, and forming a top electrode (e.g., top electrode 314) wrapping around the MTJ layer. In some embodiments, the memory cell (e.g., MTJ cell 211 or 320) vertically overlaps with the second transistor (e.g., BEOL transistor 150).

In some embodiments, a memory device includes a first transistor, a second transistor above the first transistor, and an memory cell above the first transistor. The memory cell (e.g., MTJ cell 211 or 320) comprises a bottom electrode (e.g., bottom electrode 212 or 310), a resistance switching layer (e.g., MTJ layer 214 or 312) over the bottom electrode, and a top electrode (e.g., top electrode 216 or 314) over the resistance switching layer. The resistance switching layer forms a first interface with the bottom electrode. The first interface comprises a first portion extending in a first direction toward the substrate and a second portion extending in a second direction different from the first direction. In a cross-sectional view, a ratio of a length of the first portion of the first interface to a length of the second portion of the second interface is greater than a height-to-width ratio of the second transistor. The first portion of the first interface is larger than the second portion of the first interface. In some embodiments, the resistance switching layer forms a second interface with the top electrode. The second interface comprises a third portion extending in the first direction toward the substrate and a fourth portion extending in the second direction different from the third portion. The third portion of the second interface is larger than the fourth portion of the second interface. In some embodiments, the memory device further includes a second transistor (e.g., BEOL transistor 150, 150A or 150B) above first transistor and electrically connected to the memory cell. In some embodiments, the second transistor has a gate (e.g., BEOL transistor 150) and a channel layer (e.g., channel layer 147) above the gate and below the memory cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a metal interconnect structure within a first dielectric layer over a substrate;
forming a second dielectric layer over the metal interconnect structure;
etching an opening in the second dielectric layer and over a portion of the metal interconnect structure;
depositing a bottom electrode layer in the opening;
depositing a magnetic tunnel junction (MTJ) layer in the opening and over the bottom electrode layer;
depositing a top electrode layer in the opening and over the MTJ layer; and
removing portions of the top electrode layer, the MTJ layer, the bottom electrode layer outside the opening in the second dielectric layer to form a top electrode, an MTJ stack, and a bottom electrode within the opening in the second dielectric layer.

2. The method of claim 1, wherein the top electrode layer is deposited until the opening in the second dielectric layer is overfilled with the top electrode layer.

3. The method of claim 1, wherein the opening in the second dielectric layer has a width and a depth greater than the width.

4. The method of claim 1, wherein the top electrode has a width and a height greater than the width.

5. The method of claim 1, wherein the MTJ stack forms an interface with the top electrode, and the interface extends further in a vertical direction than in a lateral direction.

6. The method of claim 1, wherein the MTJ stack forms an interface with the bottom electrode, and the interface extends further in a vertical direction than in a lateral direction.

7. The method of claim 1, wherein the portions of the top electrode layer, the MTJ layer, the bottom electrode layer outside the opening in the second dielectric layer are removed by a chemical mechanical polish (CMP) process.

8. The method of claim 1, further comprising:
forming a transistor prior to forming the metal interconnect structure, the transistor having a gate over the substrate, and a channel layer over the gate.

9. The method of claim 8, wherein the channel layer wraps around at least three sides of the gate.

10. A method comprising:
forming a first transistor over a substrate;
forming a first interconnect structure over the first transistor;
forming a second transistor over the first interconnect structure, wherein the second transistor comprises a gate structure and a channel layer over the gate structure;
forming a second interconnect structure over the second transistor; and
forming a memory cell over the second interconnect structure, the memory cell being electrically connected to the second transistor by using the second interconnect structure, wherein the channel layer of the second transistor is below the memory cell and above the gate structure of the second transistor.

11. The method of claim 10, wherein the memory cell comprises an MTJ layer between two electrodes, the MTJ layer extends further in a vertical direction than in a lateral direction.

12. The method of claim 10, wherein the memory cell comprises an MTJ layer between two electrodes, and the MTJ layer has a U-shaped cross-sectional profile.

13. The method of claim 10, wherein the memory cell comprises an MTJ layer between two electrodes, and the MTJ layer has an inverted U-shaped cross-sectional profile.

14. The method of claim 10, wherein forming the memory cell comprises:
forming a dielectric layer over the first interconnect structure;
forming an opening in the dielectric layer; and
after forming the opening in the dielectric layer, forming the memory cell in the opening in the dielectric layer.

15. The method of claim 10, wherein forming the memory cell comprises:
forming a bottom electrode over the first interconnect structure;
forming an MTJ layer wrapping around the bottom electrode; and
forming a top electrode wrapping around the MTJ layer.

16. The method of claim 10, wherein the memory cell vertically overlaps with the second transistor.

17. A memory device comprising:
a first transistor over a substrate;
a second transistor above the first transistor; and
a memory cell above the first transistor and the second transistor, wherein the memory cell comprises a bottom electrode, a resistance switching layer over the bottom electrode, and a top electrode over the resistance switching layer, the resistance switching layer forms a first interface with the bottom electrode, wherein the first interface comprises a first portion extending in a first direction toward the substrate and a second portion extending in a second direction different from the first direction, wherein the first portion of the first interface is larger than the second portion of the first interface, wherein in a cross-sectional view, a ratio of a length of the first portion of the first interface to a length of the second portion of the second interface is greater than a height-to-width ratio of the second transistor.

18. The memory device of claim 17, wherein the resistance switching layer forms a second interface with the top electrode, the second interface comprises a third portion extending in the first direction toward the substrate and a fourth portion extending in the second direction different from the first direction, wherein the third portion of the second interface is larger than the fourth portion of the second interface.

19. The memory device of claim 17, wherein the second transistor is electrically connected to the memory cell.

20. The memory device of claim 19, wherein the second transistor has a gate and a channel layer above the gate and below the memory cell.
